(19) United States
(12) Patent Application Publication
(10) Pub. No.: US 2011/0018085 A1
(43) Pub. Date: Jan. 27, 2011

(54) SILICON PHOTOELECTRIC MULTIPLIER HAVING CELL STRUCTURE

(76) Inventors: Sung yong AN, Gyunggi-do (KR); Koung Soo Kwon, Gyunggi-do (KR); Chae Dong Go, Gyunggi-do (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/551,350

(22) Filed: Aug. 31, 2009

(30) Foreign Application Priority Data
Jul. 23, 2009 (KR) 10-2009-0067400

(51) Int. Cl. H01L 31/02; H01L 31/0216

(52) U.S. Cl. 257/437; 257/446; 257/461; 257/E31.11; 257/E31.119

(57) ABSTRACT

Disclosed is a silicon photoelectric multiplier having a cell structure, which includes a first type silicon substrate; a plurality of cells including a first type epitaxial layer formed on the substrate, a high concentration first type conductive layer formed on the epitaxial layer, and a high concentration second type conductive layer doped with a second type opposite the first type and formed on the high concentration first type conductive layer; a trench formed to optically separate the plurality of cells; and a guard ring formed on an outer wall of the trench so as to reach a bottom surface of the first type epitaxial layer, thus further increasing the degree of optical separation to thereby increase light detection efficiency.

### CROSS REFERENCE TO RELATED APPLICATION

This application claims the benefit of Korean Patent Application No. 10-2009-0067400, filed Jul. 23, 2009, entitled “Photoelectric multiplier using semiconductor and cell structure thereof”, which is hereby incorporated by reference in its entirety into this application.

### BACKGROUND OF THE INVENTION

1. Technical Field

The present invention relates to a photoelectric multiplier having a cell structure, and particularly to a silicon photoelectric multiplier having a cell structure, which is manufactured using a silicon semiconductor and includes separation elements for separating a plurality of cells.

2. Description of the Related Art

A single photon detection optical sensor able to obtain information about a single photon from a photodetector for converting incident light into electrical signals is mainly exemplified by a photomultiplier tube (PMT) in vacuum tube form. The other examples thereof may include a semiconductor type PIN photodiode, an Avalanche photodiode, a Giger mode Avalanche photodiode and so on.

However, the PMT in vacuum tube form which is conventionally used is disadvantageous because it has a large volume, requires a high voltage of 1 kV or more and is expensive. Furthermore, because the PMT is affected by a magnetic filed, it cannot be utilized in equipment such as magnetic resonance imaging (MRI) which uses a large magnetic field.

### SUMMARY OF THE INVENTION

Accordingly, the present invention has been made keeping in mind the problems encountered in the related art and the present invention intends to provide a silicon photoelectric multiplier having a cell structure, which is an inexpensive optical sensor which has bias voltage properties and is not affected by a magnetic field.

An aspect of the present invention provides a silicon photoelectric multiplier, which includes a first type silicon substrate; a plurality of cells including a first type epitaxial layer formed on the substrate, a high concentration first type conductive layer formed on the epitaxial layer, and a high concentration second type conductive layer doped with a second type opposite the first type and formed on the high concentration first type conductive layer; a trench formed to optically separate the plurality of cells; and a guard ring formed on an outer wall of the trench so as to reach a bottom surface of the first type epitaxial layer.

In the aspect, the first type may be a P type and the second type may be an N type.

In the aspect, the silicon photoelectric multiplier may further include an anti-reflection coating layer formed on an inner wall of the trench and an insulating material charged in the anti-reflection coating layer.

In the aspect, the insulating material may be one or more selected from the group consisting of polyimide, polyester, polypropylene, polyethylene, ethylene vinyl acetate (EVA), acrylonitrile styrene acrylate (ASA), polymethylmethacrylate (PMMA), acrylonitrile butadiene styrene (ABS), polyamide, polyoxymethylene, polycarbonate, modified polyphenylene oxide (PPO), polybutylene terephthalate (PBT), polyethylene terephthalate (PET), polyester elastomer, polyphenylene sulfide (PPS), polysulfone, polyphthalic amide, polyether sulfone (PES), polyamide imide (PAI), polyether imide, polyether ketone, liquid crystal polymer, polyarylate, polytetrafluoroethylene (PEFE), and polysilicon.

In the aspect, the guard ring may be doped with a second type using an implanting process after formation of the trench, and may have a dopant concentration of 10¹⁴˜10¹⁸ cm⁻³.

In the aspect, the guard ring may be formed to surround an outer wall of a lower end of the trench.

In the aspect, the guard ring may be formed to surround the outer wall of the trench up to the first type epitaxial layer.

In the aspect, the guard ring may be formed to surround an entire outer wall of the trench.

In the aspect, the high concentration second type conductive layer may be spaced apart from the trench or the guard ring and the high concentration first type conductive layer between the trench or the guard ring and the high concentration first type conductive layer so as to enclose the high concentration first type conductive layer up to a depth of the high concentration first type conductive layer. As such, the guard ring may be formed to surround an outer wall of a lower end of the trench. The guard ring may be formed to surround the outer wall of the trench up to the first type epitaxial layer. The guard ring may be formed to surround an entire outer wall of the trench.

In the aspect, the first type silicon substrate may have a dopant concentration of 10¹⁷˜10²⁰ cm⁻³.

In the aspect, the first type epitaxial layer may have a dopant concentration of 10¹⁴˜10¹⁸ cm⁻³ and a thickness of 3˜10 μm.

In the aspect, the high concentration first type conductive layer may have a dopant concentration of 10¹⁵˜10¹⁸ cm⁻³, and the high concentration second type conductive layer may have a dopant concentration of 10¹⁸˜10²⁰ cm⁻³.

Also, the silicon photoelectric multiplier may further include an anti-reflection coating layer formed on the high concentration second type conductive layer on which light is incident; a voltage distribution bus formed on the anti-reflection coating layer to distribute voltage to the high concentration second type conductive layer; and a polysilicon resistor formed on the anti-reflection coating layer per cell to connect the high concentration second type conductive layer and the voltage distribution bus.

The anti-reflection coating layer may include any one selected from the group consisting of polysilicon, Si₃N₄ and indium tin oxide (ITO), or may include either a combination of polysilicon and ITO or a combination of polysilicon and Si₃N₄, and may have a thickness of about 20˜100 nm.

The polysilicon resistor may have a resistance of 1 kΩ˜100 MΩ.

### BRIEF DESCRIPTION OF THE DRAWINGS

The features and advantages of the present invention will be more clearly understood from the following detailed description taken in conjunction with the accompanying drawings, in which:

FIG. 1 is a cross-sectional view showing a silicon photoelectric multiplier according to a first embodiment of the present invention;

FIG. 2 is a cross-sectional view showing a silicon photoelectric multiplier according to a second embodiment of the present invention;

FIG. 3 is a cross-sectional view showing a silicon photoelectric multiplier according to a third embodiment of the present invention; and

FIG. 4 is a cross-sectional view showing a silicon photoelectric multiplier according to a fourth embodiment of the present invention.

### DESCRIPTION OF SPECIFIC EMBODIMENTS

Hereinafter, a detailed description will be given of a silicon photoelectric multiplier having a cell structure according to embodiments of the present invention with reference to the accompanying drawings. Throughout the drawings, the same reference numerals refer to the same or similar elements, and redundant descriptions are omitted.

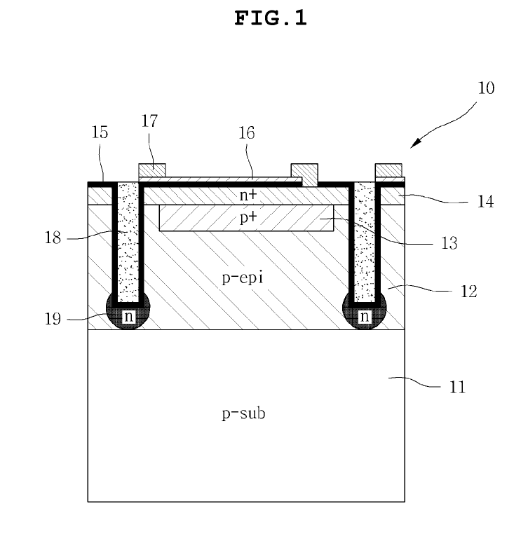

FIG. 1 is a cross-sectional view showing a silicon photoelectric multiplier according to a first embodiment of the present invention. With reference to FIG. 1, the silicon photoelectric multiplier 10 composed of a plurality of cells includes a P type silicon substrate 11, a P type epitaxial layer 12, a high concentration P type conductive layer 13, a high concentration N type conductive layer 14, a silicon oxide layer 15 (polysilicon), a polysilicon resistor 16, and a voltage distribution bus 17. Further, in order to optically separate the plurality of cells, separation elements, for example, trenches 18 and guard rings 19 are coupled and disposed between the cells.

The P type silicon substrate 11 has a dopant concentration of 10¹⁷˜10²⁰ cm⁻³, and the P type epitaxial layer 12 which spatially changes and has a thickness of about 3˜10 μm is grown on the P type silicon substrate 11. As such, the P type epitaxial layer 12 has a dopant concentration of 10¹⁴˜10¹⁸ cm⁻³.

Sequentially provided on the P type epitaxial layer 12 are the high concentration P type conductive layer 13 having a dopant concentration of 10¹⁵˜10¹⁸ cm⁻³ and the high concentration N type conductive layer 14 having a dopant concentration of 10¹⁸˜10²⁰ cm⁻³. In this case, PN junction occurs between the high concentration P type conductive layer 13 and the high concentration N type conductive layer 14, thus forming a depletion layer. Depending on the concentration of each of the conductive layers 13, 14, the depth of the depletion layer may be adjusted, thus controlling breakdown voltage. Specifically, as the conductive layers 13, 14 are doped at higher concentration, the depth of the depletion layer is reduced and thus breakdown voltage is also reduced.

As such, the reduction of the breakdown voltage indicates that bias voltage which is typically formed at voltages equal to or exceeding the breakdown voltage may be reduced.

Hence, the concentration of each of the conductive layers 13, 14, in particular, the concentration of the high concentration P type conductive layer 13, is controlled, thereby reducing the bias voltage (to 20 V or less). When the bias voltage is reduced in this way, dark rate which is noise in the silicon photoelectric multiplier 10 according to the present invention may also be reduced.

The silicon oxide layer 15, which is a kind of insulating layer, is an anti-reflection coating (ARC) layer in which the amount of reflected incident light is reduced upon incidence of light thereupon to thus increase cell sensitivity which results in increased light detection efficiency over a wide wavelength range. The silicon oxide layer 15 may be made of any one selected from among polysilicon, Si₃N₄ and ITO, or may be made of either a combination of polysilicon and ITO or a combination of polysilicon and Si₃N₄, and has a thickness of about 20˜100 nm.

Disposed on the silicon oxide layer 15 is the polysilicon resistor 16 having a resistance of 1 kΩ˜100 MΩ per cell, this polysilicon resistor 16 functioning to connect the high concentration N type conductive layer 14 and the voltage distribution bus 17 for distributing voltage to the high concentration N type conductive layer 14.

The voltage distribution bus 17 is connected to the high concentration N type conductive layer 14 so as to distribute the voltage, and is made of metal such as aluminum (Al).

The separation elements 18, 19 are disposed between the cells in order to optically separate the cells. As shown in FIG. 1, the separation elements, for example, the trenches 18 and the guard rings 19 are provided in the form of being coupled together such that they reach the bottom surface of the P type epitaxial layer 12.

The separation elements may be provided by forming the trenches 18 and then forming the N type guard rings 19 under the trenches 18 using an implanting process. The N type guard rings 19 have a dopant concentration of 10¹⁴˜10¹⁸ cm⁻³.

The trenches 18 have the silicon oxide layer 15 formed on the inner walls thereof to prevent the reflection of incident light, and are filled with an insulating material.

The insulating material may be one or more selected from the group consisting of polyimide, polyester, polypropylene, polyethylene, EVA, ASA, PMMA, ABS, polyamide, polyoxymethylene, polycarbonate, modified PPO, PBT, PET, polyester elastomer, PPS, polysulfone, polyphthalic amide, PES, PAI, polyether imide, polyether ketone, liquid crystal polymer, polyarylate, PEFE, and polysilicon.

In order to optically separate the cells composed of the P type epitaxial layer, the high concentration P type conductive layer and the high concentration N type conductive layer, the separation elements may include the trenches 18 and the guard rings 19 coupled together, thus further increasing the degree of optical separation to thereby increase light detection efficiency.

Furthermore, the trenches 18 are not empty but are filled with the insulating material, resulting in a silicon photoelectric multiplier having a stronger cell structure.

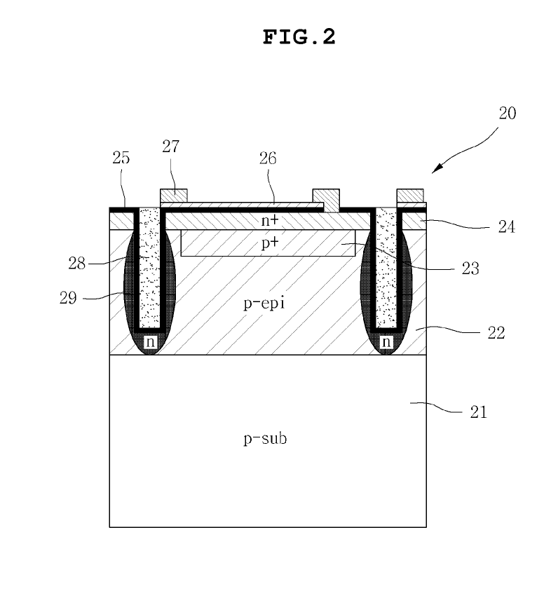

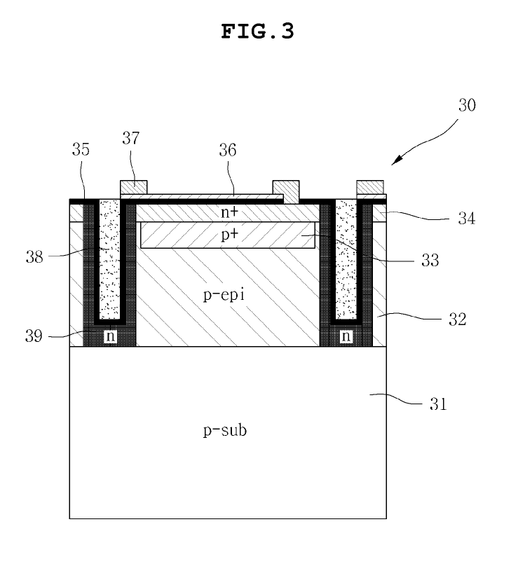

FIGS. 2 and 3 are cross-sectional views showing silicon photoelectric multipliers according to second and third embodiments of the present invention, respectively.

The silicon photoelectric multipliers 20, 30 of FIGS. 2 and 3 have the same configuration as that of the silicon photoelectric multiplier 10 of FIG. 1, with the exception of the shape of the guard rings 29, 39. Thus the description for the same elements is omitted.

With reference to FIG. 2, the guard rings 29 of the silicon photoelectric multiplier 20 according to the second embodiment of the present invention are formed to surround not only the outer walls of the lower ends of the trenches 28 but also the outer walls of the trenches 28 surrounded up to the P type epitaxial layer 22, unlike the guard rings 19 of FIG. 1. The guard rings 29 are formed using an implanting process as in the formation of the guard rings 19 of FIG. 1. The guard rings 29 formed as shown in FIG. 2 may remarkably increase the degree of optical separation compared to the guard rings 19 of FIG. 1 and may reduce the dark rate which may occur between the high concentration P type conductive layer 23 and the separation elements.

With reference to FIG. 3, the guard rings 39 of the silicon photoelectric multiplier 30 according to the third embodiment of the present invention are formed on the entire outer walls of the trenches 39, unlike the guard rings 19, 29 of FIGS. 1 and 2. The guard rings 39 are formed using an implanting process as in the formation of the guard rings 19, 29 of FIGS. 1 and 2.

The guard rings 39 formed as shown in FIG. 3 may more remarkably increase the degree of optical separation compared to the guard rings 19, 29 of FIGS. 1 and 2, and accordingly may further reduce the dark rate. The guard rings 39 are spaced apart from the high concentration P type conductive layer 33 by an interval of about 2 μm.

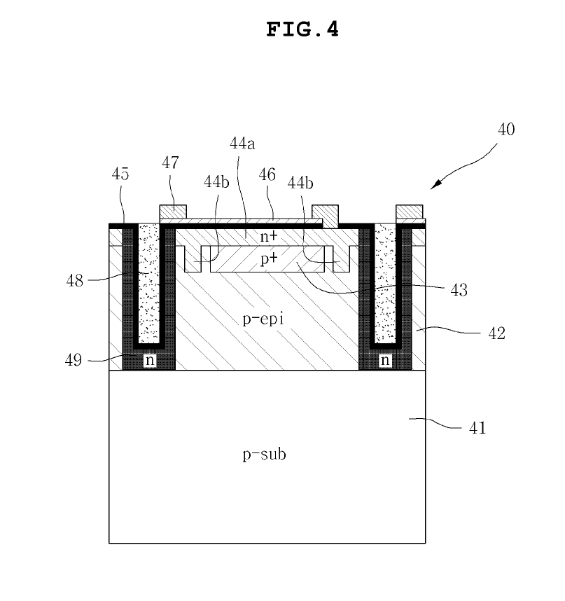

FIG. 4 is a cross-sectional view showing a silicon photoelectric multiplier according to a fourth embodiment of the present invention. The silicon photoelectric multiplier 40 of FIG. 4 has the same configuration as that of each of the silicon photoelectric multipliers 10, 20, 30 of FIGS. 1, 2 and 3, with the exception of the shape of the high concentration N type conductive layer 44a, 44b. Thus, the description for the same elements is omitted.

With reference to FIG. 4, unlike the high concentration N type conductive layer 14, 24, 34 of FIGS. 1, 2 and 3, the high concentration N type conductive layer 44a, 44b of the silicon photoelectric multiplier 40 according to the fourth embodiment of the present invention is spaced apart from the guard rings 49 and the high concentration P type conductive layer 43 between the guard rings 49 and the high concentration P type conductive layer 43, so as to enclose the high concentration P type conductive layer 43 up to the depth of the high concentration P type conductive layer 43. The high concentration N type conductive layer 44a, 44b thus formed plays a role in that incident light is prevented once more from being reflected to adjacent cells upon reflection through a portion 44b of the high concentration N type conductive layer formed around the high concentration P type conductive layer 43, thereby much more remarkably increasing the degree of optical separation compared to when using a conventional silicon photoelectric multiplier. Consequently, according to the present invention, light detection efficiency may be further increased.

The silicon photoelectric multipliers 10, 20, 30, 40 according to the first to fourth embodiments of the present invention are advantageous because the trenches and the guard rings are used together and thus the degree of optical separation can be increased compared to when using a conventional silicon photoelectric multiplier, thereby increasing light detection efficiency.

In particular, in the silicon photoelectric multipliers 20, 30 according to the second and third embodiments of the present invention, the trenches 28, 38 and the guard rings 29, 39 formed on almost all or all of the outer walls of the trenches are provided as the optical separation elements in the form of being coupled together. Therefore, even when the interval of the trenches is narrowed, a high degree of optical separation can be attained, thus enabling the reduction in the total size of the silicon photoelectric multiplier 20, 30.

In the present invention, for convenience of the description, the silicon photoelectric multiplier able to detect a single photon is described, but it is also possible to manufacture the above silicon photoelectric multiplier having the cell structure in the form of an array so that light is incident on a large area to thus precisely detect light. Such an array may be provided in the form of, for example, 2×2, 3×3, 4×4, 8×8 and 16×16.

Furthermore, in the present invention, for convenience of the description, the silicon photoelectric multiplier including the P type substrate, the P type epitaxial layer, the high concentration P type conductive layer, the high concentration N type conductive layer and the N type guard rings is illustrative, but the opposite type silicon photoelectric multiplier is also possible and may exhibit the same effects.

As described hereinbefore, the present invention provides a silicon photoelectric multiplier having a cell structure. According to the present invention, the silicon semiconductor is used, thus reducing the manufacturing cost and simplifying the manufacturing process.

Also, because of use of the silicon semiconductor, the silicon photoelectric multiplier has very superior sensitivity properties even at low bias voltage, can be reduced in terms of its size, and is not affected by a magnetic field, and therefore can be utilized in wider fields of application.

Although the embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A silicon photoelectric multiplier, comprising:
a first type silicon substrate;
a plurality of cells including:
a first type epitaxial layer formed on the substrate,
a high concentration first type conductive layer formed on the epitaxial layer, and
a high concentration second type conductive layer doped with a second type opposite the first type and formed on the high concentration first type conductive layer;
a trench formed to optically separate the plurality of cells; and
a guard ring formed on an outer wall of the trench so as to reach a bottom surface of the first type epitaxial layer.

2. The silicon photoelectric multiplier as set forth in claim 1, wherein the first type is a P type and the second type is an N type.

3. The silicon photoelectric multiplier as set forth in claim 1, further comprising an anti-reflection coating layer formed on an inner wall of the trench and an insulating material charged in the anti-reflection coating layer.

4. The silicon photoelectric multiplier as set forth in claim 3, wherein the insulating material is one or more selected from the group consisting of polyimide, polyester, polypropylene, polyethylene, ethylene vinyl acetate, acrylonitrile styrene acrylate, polymethylmethacrylate, acrylonitrile butadiene styrene, polyamide, polyoxymethylene, polycarbonate, modified polyphenylene oxide, polybutylene terephthalate, polyethylene terephthalate, polyester elastomer, polyphenylene sulfide, polysulfone, polyphthalic amide, polyether sulfone, polyamide imide, polyether imide, polyether ketone, liquid crystal polymer, polyarylate, polytetrafluoroethylene, and polysilicon.

5. The silicon photoelectric multiplier as set forth in claim 1, wherein the guard ring is doped with a second type using an implanting process after formation of the trench, and has a dopant concentration of 10¹⁴˜10¹⁸ cm⁻³.

6. The silicon photoelectric multiplier as set forth in claim 1, wherein the guard ring is formed to surround an outer wall of a lower end of the trench.

7. The silicon photoelectric multiplier as set forth in claim 1, wherein the guard ring is formed to surround the outer wall of the trench up to the first type epitaxial layer.

8. The silicon photoelectric multiplier as set forth in claim 1, wherein the guard ring is formed to surround an entire outer wall of the trench.

9. The silicon photoelectric multiplier as set forth in claim 1, wherein the high concentration second type conductive layer is spaced apart from the trench or the guard ring and the high concentration first type conductive layer between the trench or the guard ring and the high concentration first type conductive layer so as to enclose the high concentration first type conductive layer up to a depth of the high concentration first type conductive layer.

10. The silicon photoelectric multiplier as set forth in claim 9, wherein the guard ring is formed to surround an outer wall of a lower end of the trench.

11. The silicon photoelectric multiplier as set forth in claim 9, wherein the guard ring is formed to surround the outer wall of the trench up to the first type epitaxial layer.

12. The silicon photoelectric multiplier as set forth in claim 9, wherein the guard ring is formed to surround an entire outer wall of the trench.

13. The silicon photoelectric multiplier as set forth in claim 1, wherein the first type silicon substrate has a dopant concentration of 10¹⁷˜10²⁰ cm⁻³.

14. The silicon photoelectric multiplier as set forth in claim 1, wherein the first type epitaxial layer has a dopant concentration of 10¹⁴˜10¹⁸ cm⁻³ and a thickness of 3˜10 μm.

15. The silicon photoelectric multiplier as set forth in claim 1, wherein the high concentration first type conductive layer has a dopant concentration of 10¹⁵˜10¹⁸ cm⁻³, and the high concentration second type conductive layer has a dopant concentration of 10¹⁸˜10²⁰ cm⁻³.

16. The silicon photoelectric multiplier as set forth in claim 1, further comprising an anti-reflection coating layer formed on the high concentration second type conductive layer on which light is incident; a voltage distribution bus formed on the anti-reflection coating layer to distribute a voltage to the high concentration second type conductive layer; and a polysilicon resistor formed on the anti-reflection coating layer per cell to connect the high concentration second type conductive layer and the voltage distribution bus.

17. The silicon photoelectric multiplier as set forth in claim 16, wherein the anti-reflection coating layer comprises any one selected from the group consisting of polysilicon, Si₃N₄ and indium tin oxide, or comprises either a combination of polysilicon and indium tin oxide or a combination of polysilicon and Si₃N₄, and has a thickness of about 20˜100 nm.

18. The silicon photoelectric multiplier as set forth in claim 16, wherein the polysilicon resistor has a resistance of 1 kΩ˜100 MΩ.
